(19) United States
(12) Patent Application Publication
(10) Pub. No.: US 2025/0268068 A1
(43) Pub. Date: Aug. 21, 2025

(54) DISPLAY DEVICE

(71) Applicant: LG Display Co., Ltd., Seoul (KR)

(72) Inventor: Junyoung LEE, Goyang-si (KR)

(73) Assignee: LG Display Co., Ltd., Seoul (KR)

(21) Appl. No.: 18/936,573

(22) Filed: Nov. 4, 2024

(30) Foreign Application Priority Data
Feb. 21, 2024 (KR) 10-2024-0025072

(51) Int. Cl. H10K 59/80; H10K 59/127; H10K 102/00

(52) U.S. Cl. CPC H10K 59/873; H10K 59/127; H10K 59/8793; H10K 2102/311

(57) ABSTRACT

A display device can include a display panel having an active area in which a plurality of pixels is disposed, a first non-active area adjacent to the active area, a bending area extending from one side of the first non-active area to be bent, and a second non-active area connected to the bending area. The display device further includes a micro coating layer disposed in the first non-active area, the bending area, and the second non-active area on the display panel, a driving IC disposed in the second non-active area, and a reinforcement plate disposed in the second non-active area. The reinforcement plate has one side disposed to enclose the driving IC and the other side disposed on the micro coating layer, and can further includes a groove disposed at the other side to correspond to the micro coating layer.

### CROSS-REFERENCE TO RELATED APPLICATIONS

This application claims the priority to Korean Patent Application No. 10-2024-0025072 filed on Feb. 21, 2024, in the Korean Intellectual Property Office, the entire contents of which is hereby expressly incorporated by reference into the present application.

### BACKGROUND

### Field

The present disclosure relates to a display device, and more particularly, to a display device with an improved reliability.

### Discussion of the Related Art

Currently, in a full-scale information era, a field of a display device which visually expresses electrical information signals has been rapidly developed and studies are continued to improve performances of various display devices such as a thin-thickness, a light weight, and low power consumption.

Among various display devices, a light emitting display device is a self-emitting display device since a separate light source is not needed, which is different from the liquid crystal display device. Therefore, the light emitting display device can be manufactured to have light weight and small thickness.

Further, since the light emitting display device is driven at a low voltage so that it is advantageous not only in terms of power consumption, but also in terms of color implementation, a response speed, a viewing angle, and a contrast ratio (CR). Therefore, it is expected to be utilized in various fields.

### SUMMARY OF THE DISCLOSURE

An object to be achieved by the present disclosure is to provide a display device which minimizes a size of a bezel area.

Another object to be achieved by the present disclosure is to provide a display device in which a moisture permeation defect is minimized to improve the reliability.

Objects of the present disclosure are not limited to the above-mentioned objects, and other objects, which are not mentioned above, can be clearly understood by those skilled in the art from the following descriptions.

According to an aspect of the present disclosure, a display device includes a display panel having an active area in which a plurality of pixels is disposed, a first non-active area enclosing the active area, a bending area extending from one side of the first non-active area to be bent, and a second non-active area connected to the bending area; a micro coating layer disposed in the first non-active area, the bending area, and the second non-active area on the display panel; a driving integrated circuit (IC) disposed in the second non-active area; and a reinforcement plate disposed in the second non-active area and having one side disposed to enclose the driving IC and the other side disposed on the micro coating layer, and including a groove disposed at the other side to correspond to the micro coating layer.

Other detailed matters of the example embodiments of the present disclosure are included in the detailed description and the drawings.

According to aspects of the present disclosure, a space required to protect an outside of the display panel is minimized to implement a narrow bezel.

According to an effect by the present disclosure, a contact of the display panel and the molding member is minimized to minimize the moisture permeation of the display panel.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1A is a plan view of a display device according to an example embodiment of the present disclosure before bending a display panel;

FIG. 1B is a rear view of a display device according to an example embodiment of the present disclosure;

FIG. 1C is a view obtained by excluding a molding member, a protection tape, and a flexible circuit board from FIG. 1B;

FIG. 2A is a cross-sectional view along line A-A′ of FIG. 1B;

FIG. 2B is a cross-sectional view along line B-B′ of FIG. 1B;

FIG. 3A is an enlarged plan view of an area C of FIG. 1C;

FIG. 3B is a cross-sectional view along line D-D′ of FIG. 3A;

FIG. 4 is a cross-sectional view of a display device according to another example embodiment of the present disclosure;

and

FIG. 5 is a cross-sectional view of a display device according to still another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as ‘including’, ‘having’, ‘consist of’ used herein are generally intended to allow other components to be added unless the terms are used with the term ‘only’. Any references to singular can include plural unless expressly stated otherwise.

Components are interpreted to include an ordinary error range even if not expressly stated.

When the position relation between two parts is described using the terms such as ‘on’, ‘above’, ‘below’, ‘next’, one or more parts can be positioned between the two parts unless the terms are used with the term ‘immediately’ or ‘directly’.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other. Further, the term “can” fully encompasses all the meanings and coverages of the term “can.”

Hereinafter, various embodiments of the present disclosure will be described in detail with reference to accompanying drawings. All the components of each display device according to all embodiments of the present disclosure are operatively coupled and configured.

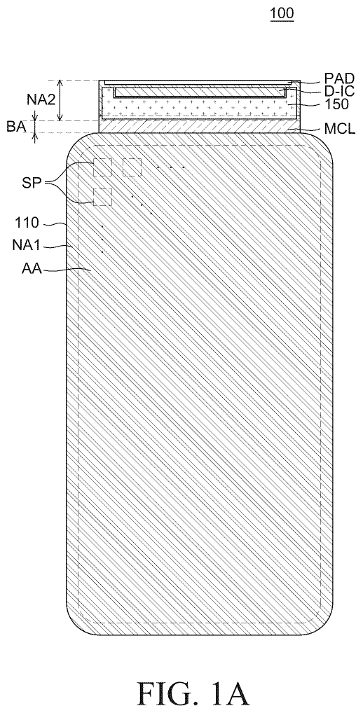

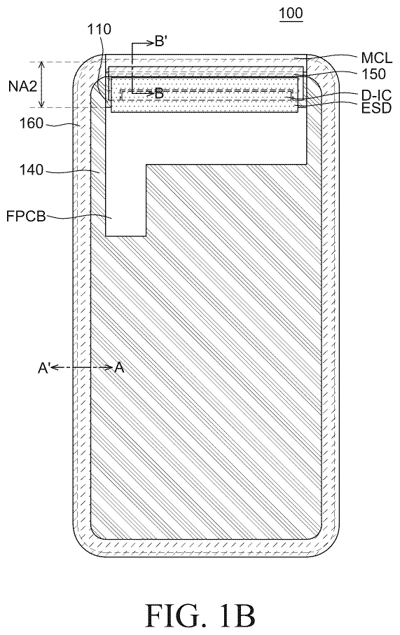

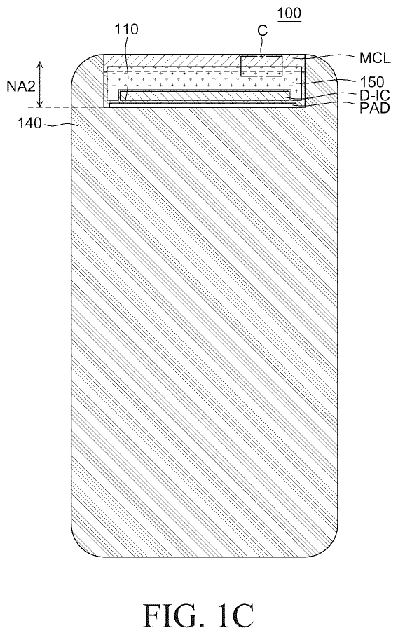

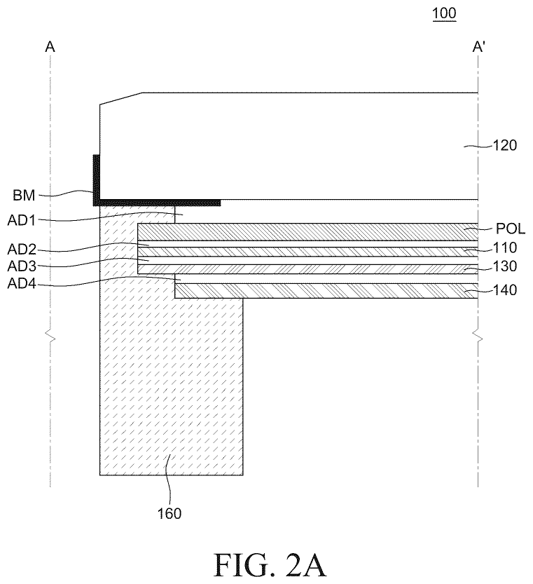

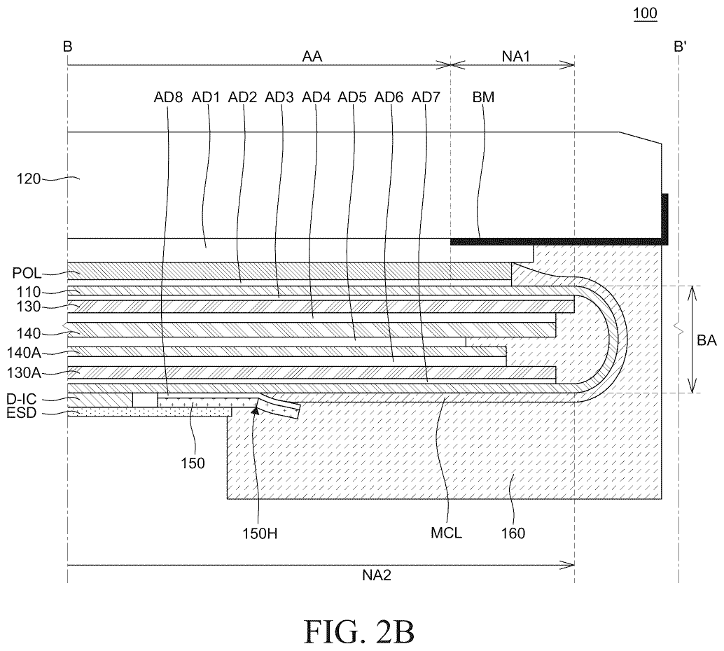

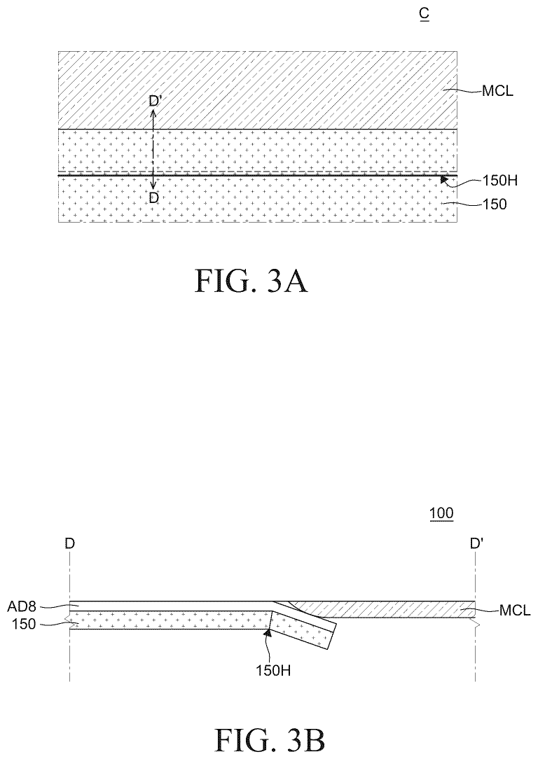

FIG. 1A is a plan view of a display device according to an example embodiment of the present disclosure before bending a display panel. FIG. 1B is a rear view of a display device according to an example embodiment of the present disclosure. FIG. 1C is a view obtained by excluding a molding member, a protection tape, and a flexible circuit board from FIG. 1B. FIG. 2A is a cross-sectional view along line A-A′ of FIG. 1B. FIG. 2B is a cross-sectional view along line B-B′ of FIG. 1B. FIG. 3A is an enlarged plan view of an area C of FIG. 1C. FIG. 3B is a cross-sectional view along line D-D′ of FIG. 3A.

In FIGS. 1A to 3B, for the convenience of description, among components of a display device 100, a display panel 110, a cover window 120, a back plate 130, a metal plate 140, a reinforcement plate 150, a molding member 160, a micro coating layer MCL, and a protection tape ESD are illustrated. In FIG. 2B, for the convenience of description, among components of a display device 100, only a reinforcement plate 150 and a micro coating layer MCL are illustrated.

Referring to FIGS. 1A to 3B, the display device 100 according to aspects of the present disclosure includes the display panel 110, the cover window 120, the back plate 130, the metal plate 140, the reinforcement plate 150, the molding member 160, a polarizer POL, a micro coating layer MCL, and a protection tape ESD.

The display panel 110 is a panel for displaying images to a user. In the display panel 110, a display element which displays images, a driving element which drives the display element, and wiring lines which transmit various signals to the display element and the driving element can be disposed.

The display element can be defined in different manners depending on the type of the display panel 110. For example, when the display panel 110 is an organic light emitting display panel 110, the display element can be an organic light emitting diode which includes an anode, an organic emission layer, and a cathode. For example, when the display panel 110 is a liquid crystal display panel, the display element can be a liquid crystal display element. Hereinafter, even though the display panel 110 is assumed as an organic light emitting display panel, the display panel 110 is not limited to the organic light emitting display panel.

The display panel 110 includes an active area AA (or display area) and a non-active area (or non-display area).

The active area AA is an area where images are displayed in the display panel 110. In the active area AA, a plurality of sub pixels SP which configures a plurality of pixels and a driving circuit for driving the plurality of sub pixels SP can be disposed.

The plurality of sub pixels SP is minimum units which configure the active area AA and a display element can be disposed in each of the plurality of sub pixels SP. For example, an organic light emitting diode which includes an anode, an organic emission layer, and a cathode can be disposed in each of the plurality of sub pixels SP, but it is not limited thereto. Further, the driving circuit for driving the plurality of sub pixels SP can include a driving element, a wiring line, and the like. For example, the driving circuit can be configured by a thin film transistor, a storage capacitor, a gate line, a data line, and the like, but is not limited thereto.

The non-active area is an area in which no image is displayed. The non-active area refers to an outer peripheral portion of the display panel 110 which encloses the active area AA. As an example, the non-active area can surround the active area AA entirely or only in part(s). The non-active area can overlap the black matrix BM. In the non-active area, various wiring lines, circuits, and the like for driving an organic light emitting diode in the active area AA are disposed. For example, in the non-active area, a link line which transmits signals to the plurality of sub pixels SP and driving circuits of the active area AA or a driving IC (D-IC) such as a gate driver integrated circuit (IC) or a data driver IC can be disposed, but it is not limited thereto.

The non-active area includes a first non-active area NA1, a bending area BA, and a second non-active area NA2.

The first non-active area NA1 is an area which encloses the active area AA and extends from the active area AA. The bending area BA can extend from one side of the first non-active area NA1 and can be bent. The second non-active area NA2 is an area which extends from the bending area BA to be disposed below the active area.

In the meantime, referring to FIGS. 1A to 1C, and 2B, the first non-active area NA1 and the second non-active area NA2 are disposed on the same plane as the active area AA or disposed to be parallel to the active area AA and maintain a flat state. For example, the first non-active area NA1 can be disposed to be flat on the same plane as the active area AA and the second non-active area NA2 is disposed below the active area AA to be parallel to the active area AA and be flat. Therefore, the active area AA, the first non-active area NA1, and the second non-active area NA2 can be referred to as non-bending areas, but are not limited thereto.

Referring to FIGS. 1A to 1C, the driving IC D-IC is disposed in the second non-active area NA2. The driving IC D-IC can supply a data signal to the plurality of sub pixels SP. For example, the driving IC D-IC samples and latches the data signal supplied from the timing controller in response to a data timing control signal supplied from the timing controller to convert the data signal into a gamma reference voltage and output the converted gamma reference voltage. The driving IC D-IC can output a data signal through the plurality of data lines. In the meantime, the driving IC D-IC is disposed on one side of the display panel 110 in a chip on panel (COP) manner to be connected to the display panel 110 or is disposed in a separate flexible film to be connected to the display panel 110 in a chip on film (COF) manner. In the display device 100 according to the example embodiment of the present disclosure, it is assumed that the driving IC D-IC is disposed in the COP manner, but it is not limited thereto.

In the second non-active area NA2 in which the driving IC D-IC is disposed, a pad unit PAD is disposed. The pad unit PAD can supply various signals and voltages to the driving IC D-IC and the plurality of sub pixels SP. For example, the pad unit PAD includes a plurality of pads disposed on the display panel 110, but is not limited thereto.

A flexible circuit board FPCB (e.g., flexible printed circuit board) can be connected to the pad unit PAD. The flexible circuit board FPCB can supply a data signal to the driving IC D-IC through the pad unit PAD. The flexible circuit board FPCB can include a first connection unit, such as a connector, to receive a data signal. For example, a controller which supplies a control signal to the display panel 110 and a frame in which the controller is disposed can be disposed below the display panel 110. A second connection unit is disposed in the frame to be connected to the first connection unit of the flexible circuit board FPCB. Therefore, the flexible circuit board FPCB can be connected to the controller by means of the connection of the first connection unit and the second connection unit and can supply a control signal to the driving IC D-IC and the display panel 110, but is not limited thereto.

Referring to FIGS. 1A to 1C, a micro coating layer MCL is disposed in the bending area BA of the display panel 110. The micro coating layer MCL is a configuration for protecting components disposed in the bending area BA of the display panel 110, for example, various wiring lines. A tensile stress is applied to the bending area BA of the display panel 110 so that the components can be cracked. Therefore, the micro coating layer MCL is coated on the components disposed in the bending area BA of the display panel 110 with a small thickness to protect the components disposed in the bending area BA. The micro coating layer MCL is formed of resin and for example, can be formed of an acrylic-based material, such as acrylate polymer, but is not limited thereto.

Referring to FIGS. 1A to 1C, the reinforcement plate 150 which encloses the driving IC D-IC is disposed in the second non-active area NA2 of the display panel 110. The reinforcement plate 150 is disposed to be spaced apart from the driving IC D-IC and the pad unit PAD. The reinforcement plate 150 is formed of a material having rigidity and can reinforce the display panel 110 which is flexible. The reinforcement plate 150 is disposed so as to enclose the periphery of the driving IC D-IC on the display panel 110 to minimize the damage of the driving IC D-IC. The reinforcement plate 150 can be formed of metal, such as copper (Cu) or stainless steel (SUS), but is not limited thereto.

The reinforcement plate 150 is disposed between the driving IC D-IC and the bending area BA. One side of the reinforcement plate 150 is disposed between the driving IC D-IC and the bending area BA so as to enclose the driving IC D-IC and the other side of the reinforcement plate 150 is disposed on the micro coating layer MCL. Therefore, in the display panel 110, an area between the driving IC D-IC and the bending area BA can be covered by the micro coating layer MCL and the reinforcement plate 150.

In the meantime, referring to FIGS. 2A, 2B, and 3B, the reinforcement plate 150 can be attached to the display panel 110 by means of the eighth adhesive layer AD8. The eighth adhesive layer AD8 can bond the reinforcement plate 150 and the display panel 110. At this time, in an overlapping portion of the reinforcement plate 150 and the micro coating layer MCL, the eighth adhesive layer AD8 can be disposed between the reinforcement plate 150 and the micro coating layer MCL. For example, the eighth adhesive layer AD8 can be formed of a pressure sensitive adhesive (PSA), but is not limited thereto.

Referring to FIGS. 3A and 3B, the reinforcement plate 150 includes a groove 150H. The groove 150H is disposed in a portion of the reinforcement plate 150 corresponding to the micro coating layer MCL. The groove 150H can extend in one direction along another end portion of the reinforcement plate 150 which is opposite to the micro coating layer MCL in the reinforcement plate 150. For example, when it is assumed that a portion of the reinforcement plate 150 which is disposed to enclose the driving IC D-IC is one side and a portion opposite to the micro coating layer MCL is the other side, the groove 150H can be disposed along a direction intersecting a direction from one side of the reinforcement plate 150 to the other side. The groove 150H can be formed by reducing a thickness by punching a surface of the reinforcement plate 150, but it is not limited thereto.

The groove 150H has an open top shape to provide a partial flexibility to the reinforcement plate 150. The groove 150H is disposed so as to correspond to the overlapping portion of the micro coating layer MCL and the reinforcement plate 150 to minimize the lifting of the reinforcement plate 150 caused by the overlapping of the micro coating layer MCL and the reinforcement plate 150. For example, the groove 150H can be disposed inside than the micro coating layer MCL in the reinforcement plate 150. Therefore, as compared with a case when the groove 150H is disposed so as to overlap the micro coating layer MCL, an area exposed between the reinforcement plate 150 and the display panel is smaller, it is not limited thereto.

In the meantime, the groove 150H can be disposed on a surface of the reinforcement plate 150 on which the eighth adhesive layer AD8 is not disposed. The groove 150H can be disposed on an opposite surface of a surface of the reinforcement plate 150 with which the eighth adhesive layer AD8 is in contact. The eighth adhesive layer AD8 is disposed between the reinforcement plate 150 and the display panel 110 so that when the groove 150H is formed on a surface on which the reinforcement plate 150 and the eighth adhesive layer AD8 are in contact, even though the groove 150H is disposed, the reinforcement plate 150 may not be movable due to the eighth adhesive layer AD8. Therefore, the groove 150H can be disposed on a surface of the reinforcement plate 150 on which the eighth adhesive layer AD8 is not disposed, but it is not limited thereto.

Referring to FIGS. 1A to 1C, as the display panel 110 is bent, the driving IC D-IC disposed in the second non-active area NA2 is disposed below the active area AA. For example, the driving IC D-IC and the flexible circuit board FPCB connected to the pad unit PAD of the display panel 110 move toward the rear surface of the display panel 110 and overlap the active area AA. Therefore, as seen from the top of the display panel 110, circuit elements, such as the driving IC D-IC and the flexible circuit board FPCB, may not be visible. Accordingly, a size of the non-active area which is visible from the top of the display panel 110 is reduced to implement a narrow bezel.

In the meantime, referring to FIG. 1C, a protection tape (ESD) is disposed on the driving IC D-IC and the reinforcement plate 150. The protection tape ESD is a configuration for protecting the driving IC D-IC from the outside. The protection tape ESD is configured with a base material including an adhesive layer to be bonded onto the driving IC D-IC and the reinforcement plate 150. For example, the protection tape ESD can be an electrostatic discharge tape and earths the driving IC D-IC, but is not limited thereto.

The display panel 110 includes a substrate, a pixel unit, and an encapsulation layer.

The substrate is a base member which supports various components of the display panel 110 and can be configured by an insulating material. The substrate is formed of a plastic material having flexibility. For example, the substrate can be formed of a plastic material, such as polyimide (PI), but is not limited thereto.

The pixel unit includes a plurality of organic light emitting diodes and a circuit for driving the organic light emitting diodes. The pixel unit can be disposed so as to correspond to the active area AA.

In the meantime, the display panel 110 can be configured by a top emission type or a bottom emission type, depending on an emission direction of light which is emitted from the organic light emitting diode.

According to the top emission type, light emitted from the organic light emitting diode is emitted to the top of the substrate on which the organic light emitting diode is formed. In the case of the top emission type, a reflective layer can be formed below the anode to allow the light emitted from the organic light emitting diode to travel above the substrate, for example, toward the cathode.

According to the bottom emission type, light emitted from the organic light emitting diode is emitted to the bottom of the substrate on which the organic light emitting diode is formed. In the case of the bottom emission type, the anode can be formed only of a transparent conductive material and the cathode can be formed of the metal material having a high reflectance to allow the light emitted from the organic light emitting diode to travel below the substrate.

Hereinafter, the description will be made by assuming that the display device 100 according to the example embodiment of the present disclosure is a top emission type, but it is not limited thereto.

The encapsulation layer is disposed so as to cover the pixel unit. The encapsulation layer seals the organic light emitting diode of the pixel unit. The encapsulation layer can protect the organic light emitting diode of the pixel unit from moisture, oxygen, impact, or the like of the outside. The encapsulation layer can be formed by alternately laminating a plurality of inorganic layers and a plurality of organic layers. For example, the inorganic layer can be formed of an inorganic material such as silicon nitride (SiNx), silicon oxide (Siox), and aluminum oxide (Alox) and the organic layer can be formed of epoxy-based or acrylic-based polymer, but they are not limited thereto.

Referring to FIGS. 2A and 2B, the cover window 120 is disposed on the front surface of the display panel 110. The cover window 120 can be a component which is exposed to the outer periphery of the display device 100 and protect the display device 100 from external shock or scratches. Further, the cover window 120 can protect the display device 100 from moisture permeating from the outside. The cover window 120 can be formed of a glass or a plastic material having a flexibility, but is not limited thereto.

A black matrix BM is disposed below the cover window 120. The black matrix BM can be disposed along the circumference of the cover window 120 on the outer periphery of the cover window 120. At this time, the area in which the black matrix BM is disposed can correspond to the first non-active area NA1. The black matrix BM can be formed of a material having a low permeability. Therefore, the black matrix BM can suppress various components disposed below the first non-active area NA1 from being visible to the outside. Further, the black matrix BM is formed of a material having a conductivity to discharge static electricity of the cover window 120.

The black matrix BM is configured by chrome (Cr), graphite, or resin including conductive particles. Here, the resin can be formed of one or more materials of acrylic resin, epoxy resin, phenolic resin, polyamides resin, polyimides resin, unsaturated polyesters resin, polyphenylene resin, polyphenylenesulfides resin, and benzocyclobutene, but is not limited thereto. Further, the conductive particle can also be formed of any one of molybdenum (Mo), chrome (Cr), titanium (Ti), nickel (Ni), neodymium (Nd), copper (Cu), and an alloy of silver (Ag) and magnesium (Mg), but is not limited thereto.

Referring to FIGS. 2A and 2B, a polarizer POL is disposed between the display panel 110 and the cover window 120. The polarizer POL can be disposed on the front surface of the display panel 110. The polarizer POL selectively transmits light to reduce the reflection of external light which is incident onto the display panel 110. Specifically, the display panel 110 includes various metal materials applied to the semiconductor element, the wiring line, and the organic light emitting diode. Therefore, the external light incident onto the display panel 110 can be reflected from the metal material so that the visibility of the display device 100 can be reduced due to the reflection of the external light. In contrast, when the polarizer POL is disposed, the polarizer POL suppresses the reflection of the external light so that the outdoor visibility of the display device 100 can be increased. However, the polarizer POL can be omitted depending on an implementation example of the display device 100, but it is not limited thereto.

The first adhesive layer AD1 is disposed between the polarizer POL and the cover window 120 and the second adhesive layer AD2 is disposed between the polarizer POL and the display panel 110. The first adhesive layer AD1 can bond the cover window 120 and the polarizer POL and the second adhesive layer AD2 can bond the polarizer POL and the display panel 110. As a result, the first adhesive layer AD1 and the second adhesive layer AD2 can bond the display panel 110 and the cover window 120. The first adhesive layer AD1 and the second adhesive layer AD2 can be formed as transparent adhesive layers so that an image of the display panel 110 is visible. For example, the first adhesive layer AD1 and the second adhesive layer AD2 can be formed of optical clear adhesives (OCA), but are not limited thereto.

The back plate 130 is disposed below the display panel 110. The back plate 130 can be disposed so as to support the display panel 110. For example, when the substrate of the display panel 110 is formed of a plastic material such as polyimide, due to the flexible property, a separate component for protecting the substrate can be necessary. Therefore, a support substrate which is formed of glass is disposed below the substrate to perform a manufacturing process of the display device 100 and the support substrate can be separated to be released after completing the manufacturing process. However, a component for supporting the substrate is necessary even after releasing the support substrate, so that a back plate 130 for supporting the substrate can be disposed below the display panel 110.

The back plate 130 can include a plastic material. For example, the back plate 130 can be formed of a plastic thin film formed of polyimide (PI), polyethylene naphthalate (PEN), polyethylene terephthalate (PET), or a combination of the polymers.

The third adhesive layer AD3 is disposed between the display panel 110 and the back plate 130. The third adhesive layer AD3 can bond the display panel 110 and the back plate 130. The third adhesive layer AD3 can be formed of a pressure sensitive adhesive (PSA), but is not limited thereto.

The metal plate 140 is disposed below the back plate 130. The metal plate 140 can protect the components of the display device 100 from external shocks. Further, the metal plate 140 serves as an earth to suppress the static electricity entering the display device 100 or easily discharge residual charges accumulated in the display device 100 to the outside. Further, the metal plate 140 easily discharges heat generated in the display device 100 to the outside. The metal plate 140 can be formed of a metal material having excellent thermal conductivity, electrical conductivity, and mechanical rigidity. For example, the metal plate 140 can be configured by copper (Cu) or stainless steel (SUS), but is not limited thereto.

The fourth adhesive layer AD4 can be disposed between the back plate 130 and the metal plate 140. The fourth adhesive layer AD4 can bond the back plate 130 and the metal plate 140 to each other. The fourth adhesive layer AD4 can be formed of a pressure sensitive adhesive (PSA), but is not limited thereto.

Referring to FIG. 2B, an additional back plate 130A and an additional metal plate 140A are disposed below the metal plate 140 corresponding to the bending area BA.

The additional back plate 130A and the additional metal plate 140A supplement the rigidity of the second non-active area NA2 of the display panel 110 disposed in the second non-active area NA2. In the meantime, the additional back plate 130A and the additional metal plate 140A can be disposed so as not to overlap the bending area BA. Therefore, the thicknesses of the configurations disposed in the bending area BA are minimized and a neutral plane of the bending area BA is easily controlled to ensure the flexibility of the bending area.

Referring to FIG. 2B, a fifth adhesive layer AD5 is disposed between the metal plate 140 and the additional metal plate 140A and a sixth adhesive layer AD6 is disposed between the additional metal plate 140A and the additional back plate 130A. The fifth adhesive layer AD5 can bond between the metal plate 140 and the additional metal plate 140A and the sixth adhesive layer AD6 can bond between the additional metal plate 140A and the additional back plate 130A. For example, the fifth adhesive layer AD5 and the sixth adhesive layer AD6 can be formed of a pressure sensitive adhesive (PSA), but are not limited thereto.

The second non-active area NA2 of the display panel 110 is disposed below the additional back plate 130A. Further, a seventh adhesive layer AD7 is disposed between the additional back plate 130A and the second non-active area NA2 of the display panel 110. The seventh adhesive layer AD7 can bond between the additional back plate 130A and the second non-active area NA2 of the display panel 110. For example, the seventh adhesive layer AD7 can be formed of a pressure sensitive adhesive (PSA), but is not limited thereto.

The molding member 160 is disposed along one end of the cover window 120 below the cover window 120. The molding member 160 seals the cover window 120, the polarizer POL, the display panel 110, the back plate 130, and the metal plate 140. Specifically, the molding member 160 can be disposed so as to enclose a lower portion of the cover window 120, a side surface of the polarizer POL, a side surface of the display panel 110, a side surface of the back plate 130, a side surface of the metal plate 140, the micro coating layer MCL, and a part of the reinforcement plate 150. The molding member 160 can suppress the permeation of the moisture or oxygen into the display device 100. Further, the molding member 160 can protect components of the display device 100 and relieve shocks applied to the display device 100.

Referring to FIGS. 1B and 2B, the molding member 160 extends inward more than the micro coating layer MCL, in the plan view. The molding member 160 is disposed inside an end of the micro coating layer MCL on which the reinforcement plate 150 is disposed. For example, the molding member 160 can be disposed so as to cover an area where the micro coating layer MCL and the reinforcement plate 150 overlap.

In the meantime, referring to FIG. 2B, the molding member 160 is disposed so as to expose the driving IC D-IC. Therefore, the driving IC D-IC is not in contact with the molding member which is formed of resin so that the moisture permeation is minimized, but it is not limited thereto.

For example, the molding member 160 can be formed by a process of removing a mold, after filling and curing the mold which is disposed to expose a bottom of the cover window 120, a side surface of the polarizer POL, a side surface of the display panel 110, a side surface of the back plate 130, a side surface of the metal plate 140, the micro coating layer MCL, and a part of the reinforcement plate 150 with a material for forming the molding member 160. However, the method of forming the molding member 160 is not limited thereto.

The molding member 160 can be formed of one or more materials of acrylic resin, epoxy resin, phenolic resin, polyamides resin, polyimides resin, unsaturated polyesters resin, polyphenylene resin, polyphenylenesulfides resin, and benzocyclobutene, but is not limited thereto.

In the display device, a separate cover unit can be disposed below the cover window so as to protect side surfaces of the components of the display device, such as a display panel. However, when a separate cover unit is disposed, in order to minimize the interference between the display panel and the cover unit, the cover unit is coupled to be spaced apart from the display panel with a predetermined distance. Therefore, in the display device in which a separate cover unit is disposed below the cover window, it is difficult to implement a narrow bezel due to the space between the display panel and the cover unit.

In the display device 100 according to the example embodiment of the present disclosure, a molding member 160 which seals the components of the display device 100 is disposed below the cover window 120 to minimize the size of the bezel area.

Specifically, the display device 100 according to the example embodiment of the present disclosure seals the components of the display device 100 by means of the molding member 160. The molding member 160 can be disposed so as to enclose from a bottom of the cover window 120 to a side surface of the polarizer POL, a side surface of the display panel 110, a side surface of the back plate 130, a side surface of the metal plate 140, the micro coating layer MCL, and a part of the reinforcement plate 150. For example, the molding member 160 is integrally formed with the display device 100 while directly enclosing the components of the display device 100 so that a separate configuration, such as a cover unit for protecting the components of the display device 100, will be omitted. Therefore, a separate space for minimizing the interference between a separate configuration, such as a cover unit and components of the display device 100 can also be omitted so that the size of the first non-active area NA1, for example, the bezel area, can be minimized. Accordingly, in the display device 100 according to the example embodiment of the present disclosure, a molding member 160 which seals the components of the display device 100 is disposed below the cover window 120 to minimize the size of the bezel area and implement a narrow bezel.

In the meantime, in the display device 100 according to the example embodiment of the present disclosure, the molding member 160 is formed of resin so that the molding member 160 can buffer an external shock on the components of the display device 100 sealed by the molding member 160, such as the display panel 110. Therefore, in the display device 100 according to the example embodiment of the present disclosure, an additional effect of buffering the external shock applied to the display device 100 by the molding member 160 formed of resin can be provided.

In the meantime, in the display device in which a molding member is disposed, a part of the display panel which is exposed from the protection layers, such as a micro coating layer and a reinforcement plate, in the second non-active area of the display panel, which is bent downwardly to the active area can be in contact with the molding member. Therefore, the moisture permeates the display panel by the molding member which is formed of resin and the components disposed in the display panel are damaged to degrade the reliability of the display device.

Therefore, a method of coating the micro coating layer so as to extend to the top of the reinforcement plate can be used so that the micro coating layer and the reinforcement plate do not expose the display panel. However, in order to dispose the micro coating layer which can be designed to have a thickness smaller than the reinforcement plate to extend to the top of the reinforcement plate, an amount of applied micro coating layer needs to be greatly increased and the resulting cost consumption can also be significant.

Further, in order to save the cost, the placement of the micro coating layer is minimized to reduce the amount of applied micro coating layer. However, in this case, the display panel can be partially exposed from the micro coating layer and the reinforcement plate.

Therefore, the reinforcement plate can be disposed above the micro coating layer. However, the reinforcement plate is formed of a rigid material so that there can be a portion of the reinforcement plate which is not in contact with the display panel due to the micro coating layer. Therefore, the portion of the display panel which is not in contact with the reinforcement plate is in contact with the molding member to cause the moisture permeation, which results in the degradation of the reliability of the display device.

In the display device 100 according to the example embodiment of the present disclosure, the reinforcement plate 150 is disposed on the micro coating layer MCL and the reinforcement plate 150 includes a groove 150H to minimize the moisture permeation of the display panel 110 due to the molding member 160.

Specifically, the groove 150H is disposed in a portion of the reinforcement plate 150 corresponding to the micro coating layer MCL. The groove 150H has an open top shape to provide a partial flexibility to the reinforcement plate 150. The groove 150H is disposed so as to correspond to the overlapping portion of the micro coating layer MCL and the reinforcement plate 150 to minimize the lifting of the reinforcement plate 150 caused by the overlapping of the micro coating layer MCL and the reinforcement plate 150. Therefore, the area of the display panel 110 between the driving IC D-IC and the bending area BA can be covered by the micro coating layer MCL and the reinforcement plate 150. Further, the contact of the display panel 110 and the molding member 160 is minimized to minimize the moisture permeation of the display panel 110 due to the molding member 160. Accordingly, in the display device 100 according to the example embodiment of the present disclosure, the reinforcement plate 150 is disposed on the micro coating layer MCL and the reinforcement plate 150 includes a groove 150H. Therefore, the moisture permeation of the display panel 110 due to the molding member 160 is minimized and the reliability of the display device 100 can be improved.

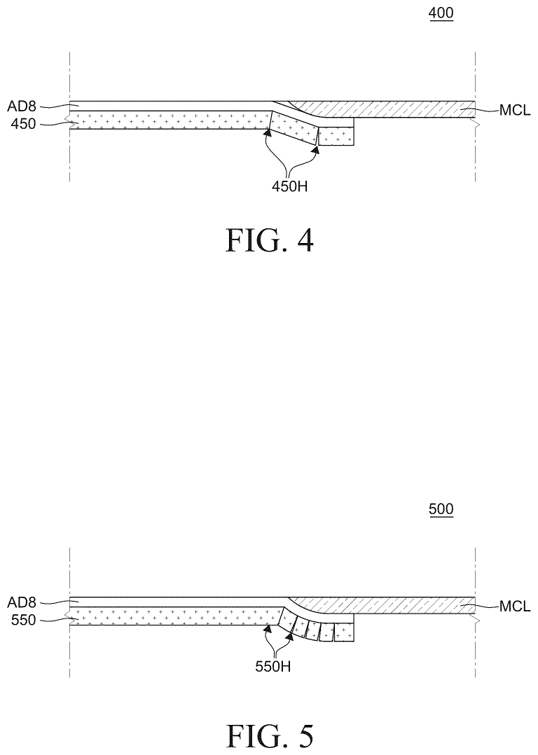

FIG. 4 is a cross-sectional view of a display device according to another example embodiment of the present disclosure. A display device 400 of FIG. 4 is the same as the display device 100 of FIGS. 1A to 3B except that a plurality of grooves 450H is disposed in a reinforcement plate 450 so that a redundant description will be omitted or may be briefly provided.

Referring to FIG. 4, in the display device 400 according to another example embodiment of the present disclosure, a plurality of grooves 450H is disposed in the reinforcement plate 450. At least a part of the plurality of grooves 450H can be disposed so as to overlap the micro coating layer MCL. For example, two grooves 450H are disposed in the reinforcement plate 450, one groove 450H is disposed inside the micro coating layer MCL in the reinforcement plate 450 and the other groove 450H is disposed so as to overlap the micro coating layer MCL. Therefore, the groove 450H disposed inside the micro coating layer MCL in the reinforcement plate 450 increases a contact surface between the reinforcement plate 450 and the display panel 110 and the groove 450H which is disposed so as to overlap the micro coating layer MCL can be configured to increase a contact surface between the reinforcement plate 450 and the micro coating layer MCL.

In the display device 400 according to another example embodiment of the present disclosure, a plurality of grooves 450H is disposed in the reinforcement plate 450 to further minimize the moisture permeation of the display panel 110 due to the molding member.

Specifically, the plurality of grooves 450H has an open top shape to provide a partial flexibility to the reinforcement plate 450. At least a part of the plurality of grooves 450H is disposed so as to overlap the micro coating layer MCL. For example, the groove 450H disposed inside the micro coating layer MCL in the reinforcement plate 450 increases a contact surface between the reinforcement plate 450 and the display panel 110 and the groove 450H which is disposed so as to overlap the micro coating layer MCL is configured to increase a contact surface between the reinforcement plate 450 and the micro coating layer MCL. Therefore, both the lifting between the reinforcement plate 450 and the display panel 110 and the lifting between the reinforcement plate 450 and the micro coating layer MCL can be minimized. Therefore, the contact of the display panel 110 and the molding member 160 is further minimized to further minimize the moisture permeation of the display panel 110 due to the molding member 160. Accordingly, in the display device 400 according to another example embodiment of the present disclosure, a plurality of grooves 450H is disposed in the reinforcement plate 450 to further minimize the moisture permeation of the display panel 110 due to the molding member 160 and further improve the reliability of the display device 400.

In the meantime, in the display device 400 according to another example embodiment of the present disclosure, at least some of the plurality of grooves 450H is disposed so as to overlap the micro coating layer MCL to minimize a protruding height of the reinforcement plate 450 above the micro coating layer MCL. Therefore, a physical interference between the reinforcement plate 450 disposed above the micro coating layer MCL and other component of the display device 400 can be minimized.

FIG. 5 is a cross-sectional view of a display device according to still another example embodiment of the present disclosure. A display device 500 of FIG. 5 is the same as the display device 100 of FIGS. 1A to 3B except that a plurality of grooves 550H is disposed in a reinforcement plate 550 so that a redundant description will be omitted or may be briefly provided.

Referring to FIG. 5, in the display device 500 according to another example embodiment of the present disclosure, a plurality of grooves 550H is disposed in the reinforcement plate 550. At least a part of the plurality of grooves 550H can be disposed so as to overlap the micro coating layer MCL. For example, five grooves 550H are disposed in the reinforcement plate 550, one groove 550H is disposed inside the micro coating layer MCL in the reinforcement plate 550 and the other four grooves 550H are disposed so as to overlap the micro coating layer MCL. Therefore, the groove 550H disposed inside the micro coating layer MCL in the reinforcement plate 550 increases a contact surface between the reinforcement plate 550 and the display panel 110 and the groove 550H which is disposed so as to overlap the micro coating layer MCL can be configured to increase the contact surface between the reinforcement plate 550 and the micro coating layer MCL.

In the display device 500 according to still another example embodiment of the present disclosure, a plurality of grooves 550H is disposed in the reinforcement plate 550 to further minimize the moisture permeation of the display panel 110 due to the molding member.

Specifically, the plurality of grooves 550H has an open top shape to provide a partial flexibility to the reinforcement plate 550. At least a part of the plurality of grooves 550H can be disposed so as to overlap the micro coating layer MCL. For example, the groove 550H disposed in the reinforcement plate 550 to be inside more than the micro coating layer MCL increases a contact surface between the reinforcement plate 550 and the display panel 110 and the groove 550H which is disposed so as to overlap the micro coating layer MCL is configured to increase the contact surface between the reinforcement plate 550 and the micro coating layer MCL. Therefore, both the lifting between the reinforcement plate 550 and the display panel 110 and the lifting between the reinforcement plate 550 and the micro coating layer MCL can be minimized. Therefore, the contact of the display panel 110 and the molding member 160 can be further minimized to further minimize the moisture permeation of the display panel 110 due to the molding member 160. Accordingly, in the display device 500 according to still another example embodiment of the present disclosure, a plurality of grooves 550H is disposed in the reinforcement plate 550 to further minimize the moisture permeation of the display panel 110 due to the molding member 160 and further improve the reliability of the display device 500.

The example embodiments of the present disclosure can also be described as follows:

According to an aspect of the present disclosure, a display device includes a display panel which includes an active area in which a plurality of pixels is disposed, a first non-active area which encloses the active area, a bending area which extends from one side of the first non-active area to be bent, and a second non-active area connected to the bending area; a micro coating layer disposed in the first non-active area, the bending area, and the second non-active area on the display panel; a driving IC disposed in the second non-active area; and a reinforcement plate which is disposed in the second non-active area and has one side disposed so as to enclose the driving IC and the other side disposed on the micro coating layer and includes a groove disposed at the other side so as to correspond to the micro coating layer.

In the second non-active area, an area between the driving IC and the bending area can be covered by the micro coating layer and the reinforcement plate.

One side of the reinforcement plate which is disposed so as to enclose the driving IC can be spaced apart from the driving IC.

The groove can be disposed along a direction intersecting a direction from one side of the reinforcement plate to the other side of the reinforcement plate.

A plurality of grooves can be disposed and at least a part of the plurality of grooves overlaps the micro coating layer.

The display device can further comprise an adhesive layer disposed between the reinforcement plate and the micro coating layer.

The groove can be disposed on an opposite surface to a surface of the reinforcement plate which is in contact with the adhesive layer.

The display device can further comprise a cover window disposed above the display panel; and a molding member which is disposed along one end of the cover window below the cover window and is disposed so as to cover a side surface of the display panel, the micro coating layer, and a part of the reinforcement plate.

The molding member can be disposed inside one end of the micro coating layer on which the reinforcement plate is disposed.

The display device can further comprise a polarizer disposed between the cover window and the display panel; a back plate disposed below the display panel; and a metal plate which is disposed below the back plate.

The molding member can be disposed so as to enclose a bottom surface of the cover window, a side surface of the polarizer, a side surface of the display panel, a side surface of the back plate, a side surface of the metal plate, the micro coating layer, and a part of the reinforcement plate.

The molding member can expose the driving IC.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto.

Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a display panel including an active area in which a plurality of pixels is disposed, a first non-active area adjacent to the active area, a bending area extending from one side of the first non-active area to be bent, and a second non-active area connected to the bending area;
a micro coating layer disposed in the first non-active area, the bending area, and the second non-active area on the display panel;
a driving integrated circuit (IC) disposed in the second non-active area; and
a reinforcement plate disposed in the second non-active area, and having one side disposed to enclose the driving IC and another side disposed on the micro coating layer, the reinforcement plate including a groove disposed at the another side to correspond to the micro coating layer.

2. The display device according to claim 1, wherein in the second non-active area, an area between the driving IC and the bending area is covered by the micro coating layer and the reinforcement plate.

3. The display device according to claim 1, wherein one side of the reinforcement plate which is disposed to enclose the driving IC is spaced apart from the driving IC.

4. The display device according to claim 1, wherein the groove is disposed along a direction intersecting a direction from one side of the reinforcement plate to another side of the reinforcement plate.

5. The display device according to claim 4, wherein a plurality of grooves is disposed and at least a part of the plurality of grooves overlaps the micro coating layer.

6. The display device according to claim 1, further comprising:
an adhesive layer disposed between the reinforcement plate and the micro coating layer.

7. The display device according to claim 6, wherein the groove is disposed on an opposite surface to a surface of the reinforcement plate which is in contact with the adhesive layer.

8. The display device according to claim 1, further comprising:
a cover window disposed on the display panel; and
a molding member disposed along one end of the cover window and covering a side surface of the display panel, the micro coating layer, and a part of the reinforcement plate.

9. The display device according to claim 8, wherein the molding member is disposed inside one end of the micro coating layer on which the reinforcement plate is disposed.

10. The display device according to claim 8, further comprising:
a polarizer disposed between the cover window and the display panel;
a back plate disposed below the display panel; and
a metal plate disposed below the back plate,
wherein the molding member is disposed to enclose a bottom surface of the cover window, a side surface of the polarizer, a side surface of the display panel, a side surface of the back plate, a side surface of the metal plate, the micro coating layer, and a part of the reinforcement plate.

11. The display device according to claim 10, wherein the molding member exposes the driving IC.
